(19) United States
(12) Patent Application Publication
(10) Pub. No.: US 2024/0196533 A1
(43) Pub. Date: Jun. 13, 2024

(54) PRINTED CIRCUIT BOARD

(71) Applicant: SAMSUNG ELECTRO-MECHANICS CO., LTD., Suwon-si (KR)

(72) Inventors: Youn Gyu Han, Suwon-si (KR); Jin Uk Lee, Suwon-si (KR); Jin Oh Park, Suwon-si (KR); Yong Duk Lee, Suwon-si (KR)

(73) Assignee: SAMSUNG ELECTRO-MECHANICS CO., LTD., Suwon-si (KR)

(21) Appl. No.: 18/208,748

(22) Filed: Jun. 12, 2023

(30) Foreign Application Priority Data
Dec. 9, 2022 (KR) 10-2022-0171240

(51) Int. Cl. H05K 1/11; H05K 1/03; H05K 3/32

(52) U.S. Cl. CPC H05K 1/115; H05K 1/03; H05K 1/111; H05K 3/323; H05K 2203/1461

(57) ABSTRACT

A printed circuit board includes a first insulating layer; a connection via penetrating through at least a portion of the first insulating layer and having an upper surface exposed to an upper surface of the first insulating layer; a cavity penetrating through at least a portion of the first insulating layer and having the upper surface of the first insulating layer as a bottom surface of the cavity; a bridge disposed in the cavity and having a first bridge pad disposed on a lower side of the bridge; and a bonding layer including conductive particles connected to the connection via and the first bridge pad.

### CROSS-REFERENCE TO RELATED APPLICATION (S)

This application claims benefit of priority to Korean Patent Application No. 10-2022-0171240 filed on Dec. 9, 2022 in the Korean Intellectual Property Office, the disclosure of which is incorporated herein by reference in its entirety.

### TECHNICAL FIELD

The present disclosure relates to a printed circuit board.

Recently, to process amounts of data exponentially increased due to the development of artificial intelligence (AI) technology and the like, multi-chip packages, including memory chips such as High Bandwidth Memory (HBM) and processor chips such as a Central Processing Unit (CPU), a Graphics Processing Unit (GPU), an Application Special Specific Integrated Circuit (ASIC), a Field Programmable Gate Array (FPGA) and the like, have been used. In the substrate structure in which various chips are mounted on the substrate, research into simplifying chip connections and signal pathways and for diversification and to improve reliability is ongoing.

### SUMMARY

An aspect of the present disclosure is to provide a printed circuit board in which up-and-down connections of signal paths may be diversified on a printed circuit board on which electronic components, chips and the like are to be mounted.

An aspect of the present disclosure is to provide a printed circuit board on which a signal path may be more simply implemented.

An aspect of the present disclosure is to provide a method of manufacturing a printed circuit board, in which reliability may be improved.

According to an aspect of the present disclosure, a printed circuit board includes a first insulating layer; a connection via penetrating through at least a portion of the first insulating layer and having an upper surface exposed to an upper surface of the first insulating layer; a cavity penetrating through at least a portion of the first insulating layer and having the upper surface of the first insulating layer as a bottom surface of the cavity; a bridge disposed in the cavity and having a first bridge pad disposed on a lower side of the bridge; and a bonding layer including conductive particles connected to the connection via and the first bridge pad.

According to an aspect of the present disclosure, a printed circuit board includes a first insulating layer; a pad buried in an upper side of the first insulating layer and having a portion of a side surface and an upper surface protruding toward an upper surface of the first insulating layer; a cavity penetrating through a portion of the first insulating layer and having the upper surface of the first insulating layer as a bottom surface of the cavity; a bridge disposed in the cavity and having a first bridge pad disposed on a lower side of the bridge; and a bonding layer including conductive particles electrically connected to the pad and the first bridge pad.

According to an aspect of the present disclosure, a printed circuit board includes a first insulating layer in which a first via is disposed; a second insulating layer which is disposed on the first insulating layer and in which a second via is disposed; a cavity penetrating through the second insulating layer and a portion of the first insulating layer; a bridge disposed in the cavity and having a bridge pad; and a bonding layer disposed between the first insulating layer and the bridge and including conductive particles disposed between the first via and the bridge pad. The first via and the second via are tapered in a same direction.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a perspective view schematically illustrating an example of an electronic device;

FIG. 3 is a schematic cross-sectional view of a printed circuit board according to an example;

FIG. 4 is a schematic cross-sectional view of a printed circuit board according to another example; and

FIG. 5 is a schematic cross-sectional view of a printed circuit board according to another example.

### DETAILED DESCRIPTION

Hereinafter, the present disclosure will be described with reference to the accompanying drawings. The shapes and sizes of elements in the drawings may be exaggerated or reduced for clearer description.

### Electronic Device

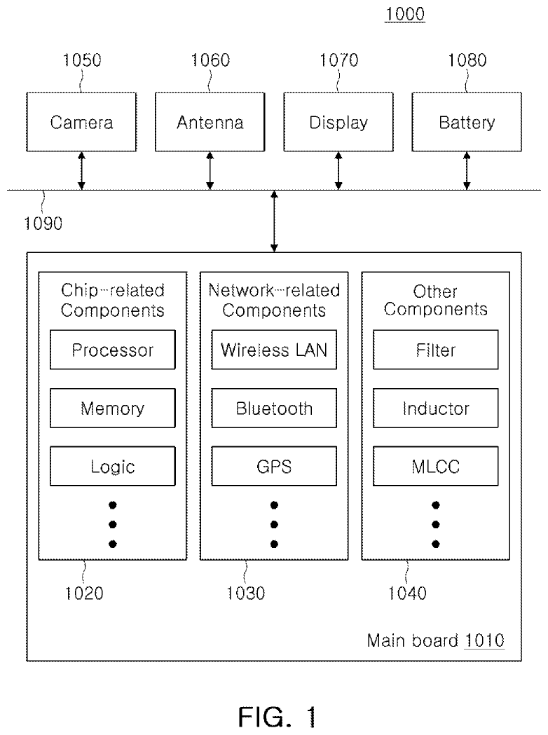

FIG. 1 is a schematic block diagram illustrating an example of an electronic device system.

Referring to FIG. 1, an electronic device 1000 may accommodate a mainboard 1010 therein. The mainboard 1010 may include chip related components 1020, network related components 1030, other components 1040, and the like, physically or electrically connected thereto. These components may be connected to others to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip related components 1020 are not limited thereto, but may also include other types of chip related components. In addition, the chip related components 1020 may be combined with each other.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+ (HSPA+), high speed downlink packet access+ (HSDPA+), high speed uplink packet access+ (HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, but may also include a variety of other wireless or wired standards or protocols. In addition, the network related components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, but may also include passive components used for various other purposes, or the like. In addition, other components 1040 may be combined with each other, together with the chip related components 1020 or the network related components 1030 described above.

Depending on a type of the electronic device 1000, the electronic device 1000 may include other components that may or may not be physically or electrically connected to the mainboard 1010. These other components may include, for example, a camera module 1050, an antenna 1060, a display device 1070, a battery 1080, an audio codec (not illustrated), a video codec (not illustrated), a power amplifier (not illustrated), a compass (not illustrated), an accelerometer (not illustrated), a gyroscope (not illustrated), a speaker (not illustrated), a mass storage unit (for example, a hard disk drive) (not illustrated), a compact disk (CD) drive (not illustrated), a digital versatile disk (DVD) drive (not illustrated), or the like. However, these other components are not limited thereto, but may also include other components used for various purposes depending on a type of electronic device 1000, or the like.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, but may be any other electronic device processing data.

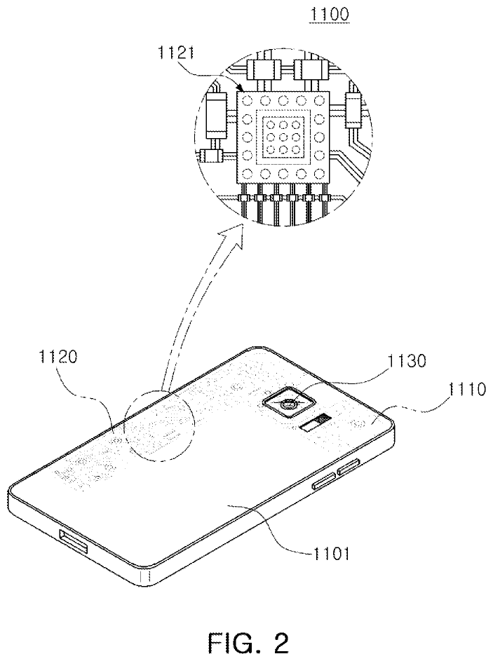

FIG. 2 is a schematic perspective view illustrating an example of an electronic device.

Referring to the drawing, the electronic device may be, for example, a smartphone 1100. A motherboard 1110 is accommodated inside the smartphone 1100, and various components 1120 are physically and/or electrically connected to the motherboard 1110. In addition, other components that may or may not be physically and/or electrically connected to the motherboard 1110, such as the camera module 1130 and/or the speaker 1140, are accommodated therein. Some of the components 1120 may be the aforementioned chip-related components, for example, the component package 1121, but is not limited thereto. The component package 1121 may be in the form of a printed circuit board on which electronic components including active components and/or passive components are surface mounted. Alternatively, the component package 1121 may be in the form of a printed circuit board in which active components and/or passive components are embedded. On the other hand, the electronic device is not necessarily limited to the smartphone 1100, and as described above, may be other electronic devices, of course.

### Printed Circuit Board

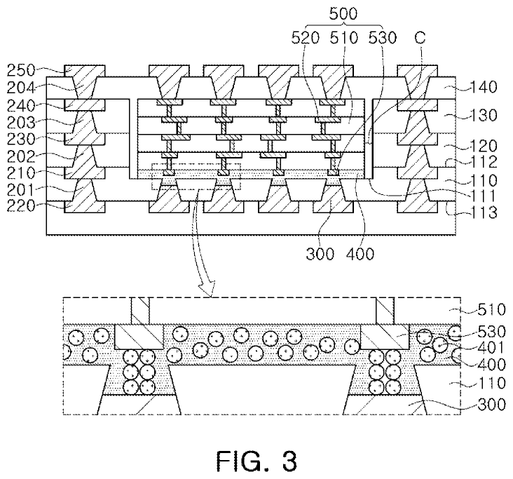

FIG. 3 is a cross-sectional view schematically illustrating a printed circuit board according to an example.

Referring to FIG. 3, a printed circuit board according to an example may include a first insulating layer 110 having a first surface 111, a second surface 112, and a third surface 113 opposite to the first and second surfaces 111 and 112, a connection via 300 penetrating through at least a portion of the first insulating layer 110 and having one surface exposed to the first surface 111 of the first insulating layer 110, a second insulating layer 120 disposed on the second surface 112 of the first insulating layer 110, a cavity C passing through at least a portion of the first insulating layer 110 and the second insulating layer 120 and having the first surface 111 of the first insulating layer 110 as a bottom surface, a bridge 500 disposed in the cavity C and including a bridge pad 530, and a bonding layer 400 interposed between the bridge 500 and the first insulating layer 110. The bonding layer 400 may include conductive particles 401 electrically connected to the connection via 300 and the bridge pad 530.

The first insulating layer 110 may include an insulating material. Examples of the insulation material may include thermosetting resins such as epoxy resins, thermoplastic resins such as polyimide, or materials containing inorganic fillers, organic fillers, and/or glass fibers (Glass Fiber, Glass Cloth, and/or Glass Fabric) together with such resins. The insulating material may be a photosensitive material and/or a non-photosensitive material. For example, as the insulating material, Solder Resist (SR), Ajinomoto Build-up Film (ABF), FR-4, Bismaleimide Triazine (BT), Prepreg (PPG), Resin Coated Copper (RCC), Copper Clad Laminate (CCL), or the like may be used, but the present disclosure is not limited thereto, and other polymer materials may be used.

The first insulating layer 110 may include a first surface 111, a second surface 112, and a third surface 113. The first surface 111 corresponds to an area where the bridge 500 is mounted, and may be provided as a bottom surface of a cavity C, which will be described later. The second surface 112 is disposed in the same direction as the first surface 111 and has a step difference with the first surface 111, and the third surface 113 may correspond to a surface facing the first surface 111 and the second surface 112. The first surface 111 may have a step with the second surface 112, which may correspond to the traces of the stopper layer in the process of processing the cavity C, which will be described later.

A printed circuit board according to an example may include a second insulating layer 120. The second insulating layer 120 may be disposed on the second surface 112 of the first insulating layer 110. The second insulating layer 120 may include an insulating material, and may include the same insulating material as the first insulating layer 110, but is not limited thereto, and an insulating material that may be used as the first insulating layer 110 may include one of them. Meanwhile, the printed circuit board according to one example may further include a third insulating layer 130 and a fourth insulating layer 140. The third insulating layer 130 and the fourth insulating layer 140 may include an insulating material, and may include the same insulating material as the first insulating layer 110, but are not limited thereto. Although the number of insulating layers of the printed circuit board is illustrated as four in FIG. 3, it is not limited thereto, and may include a larger number of insulating layers or a smaller number of insulating layers.

A printed circuit board according to an example may include a first circuit pattern 210. The first circuit pattern 210 is buried on the second surface 112 side of the first insulating layer 110, and one surface of the first circuit pattern 210 may be exposed as the second surface 112 of the first insulating layer 110.

On the other hand, the structure in which the first circuit pattern 210 is buried on the second surface 112 side of the first insulating layer 110 indicates that the first circuit pattern 210 is buried in the second surface 112 of the first insulating layer 110 so that the side surface of the first circuit pattern 210 is covered by the first insulating layer 110, and one surface of the first circuit pattern 210 refers to a structure exposed to the second surface 112 of the first insulating layer 110. In this case, the exposed structure does not mean that one side of the first circuit pattern 210 is exposed to the outside of the printed circuit board, and may mean that one surface of the first circuit pattern 210 is not covered by the first insulating layer 110.

The first circuit pattern 210 may be formed of a plurality of circuit patterns, may be formed of a metal plate, or may be composed of a plurality of circuit patterns and a metal plate formed together. A plurality of patterns and the metal plate may be formed at the same time, but may be formed in stages without being limited thereto. In addition, the first circuit pattern 210 may electrically send and receive signals with circuit patterns further disposed on other layers, but the first circuit pattern 210 may be electrically shorted to other circuit patterns to perform its function. For example, some of the first circuit patterns 210 are composed of a metal plate, and the metal plate may perform a stopper function when processing the cavity C, but is not limited thereto.

The first circuit pattern 210 may include a metal material. Examples of the metal material may include copper (Cu), aluminum (Al), silver (Ag), tin (Sn), gold (Au), nickel (Ni), lead (Pb), titanium (Ti), and/or alloys thereof. In detail, copper (Cu) may be included, but the present disclosure is not limited thereto. The first circuit pattern 210 may be formed using any one of a semi-additive process (SAP), a modified semi-additive process (MSAP), tenting (TT), and a subtractive method, but is not limited thereto. Meanwhile, in the operation of forming the first circuit pattern 210, a stopper layer for processing the cavity C may be formed together with the first circuit pattern 210. The stopper layer may correspond to a temporary configuration that is removed during processing of the cavity C and does not appear on the printed circuit board.

The cavity C may have a first surface 111 of the first insulating layer 110 as a bottom surface by penetrating through portions of the first insulating layer 110 and the second insulating layer 120. The cavity C corresponds to an area where the bridge 500 is mounted, and is not limited to the bridge 500, and other electronic components may be mounted. The bottom surface of the cavity C is composed of the first surface of the first insulating layer 110, and the wall surface of the cavity C is composed of the first insulating layer 110 and/or the second insulating layer 120. In FIG. 3, the cavity is illustrated as penetrating through the second insulating layer 120 and the third insulating layer 130, but this is merely an example, and the cavity C may pass through a larger number of insulating layers, or may pass through only the second insulating layer 120 together with a portion of the first insulating layer.

As a method for manufacturing the cavity C, a known method used in a cavity forming process may be used without limitation. For example, a mechanical drilling process such as laser processing or a blast process may be used, but is not limited thereto. At this time, some of the first circuit patterns 210 disposed on the first insulating layer 110 may function as a stopper layer, and may be removed by etching after machining the cavity C after a separate stopper layer is previously disposed on the first surface 111 of the first insulating layer 110. When a separate stopper layer is disposed on the first surface 111 of the first insulating layer 110, the first circuit pattern 210 disposed on the second surface 112 of the first insulating layer 110 and may be formed simultaneously. Then, when the stopper layer is removed after processing the cavity C, the first surface 111 of the first insulating layer 110 provided as the bottom surface of the cavity C is the second surface of the first insulating layer 110. (112) and may have a step difference. In this case, the size of the step between the first surface 111 of the first insulating layer 110 and the second surface 112 of the first insulating layer 110 may be substantially the same as the thickness of the first circuit pattern. In the present disclosure, “substantially the same” is a concept including approximate, and may include, for example, process errors or positional deviations occurring in the manufacturing process, errors during measurement, and the like. The size of the step between the first surface 111 of the first insulating layer 110 and the second surface 112 of the first insulating layer 110 may be measured as the vertical distance formed by the extended surface of the first surface 111 and the second surface 112, but the present disclosure is not limited thereto, and may mean the height of the side surface of the first insulating layer 110 extending from the first surface 111 and the second surface 112. When the stopper layer is removed after processing the cavity C, the first surface 111 and the second surface may have a step difference as much as the thickness of the stopper layer, and as described above, since the stopper layer may be formed together in the operation of forming the first circuit pattern 210, the thickness of the stopper layer and the first circuit pattern 210 may be substantially the same.

The connection via 300 may penetrate at least a portion of the first insulating layer 110. The connection via 300 may be disposed in the first insulating layer 110 so that one surface may be exposed as a first surface of the first insulating layer 110. As will be described later, the connection via 300 may function as a means for electrically connecting the bridge pad 530 of the bridge 500 and the second circuit pattern 220. On the other hand, it is not limited thereto, and electronic components may be mounted on the connecting vias 300, and other circuit patterns may be formed without mounting bridges and electrically connected to the second circuit patterns 220, and various functions may be performed depending on the design.

The connection via 300 includes a metal material. Metal materials include copper (Cu), aluminum (Al), silver (Ag), tin (Sn), gold (Au), nickel (Ni), lead (Pb), titanium (Ti), and/or alloys thereof. It may include, but may preferably include copper (Cu), but is not limited thereto. The connection via 300 may be formed simultaneously with the first circuit pattern and/or the second circuit pattern 220, but is not necessarily limited thereto, and may be formed in one of Semi Additive Process (SAP), Modified Semi Additive Process (MSAP), Tenting (TT) or a subtractive method, but the present disclosure is not limited thereto.

The connection via 300 may have a recessed structure in the first surface 111 of the first insulating layer 110. For example, the connection via 300 may have a recessed portion on the bottom surface of the cavity C. The fact that the connecting via 300 has a recessed portion on the bottom surface of the cavity C means that one surface of the connecting via 300 is formed lower than the first surface 111 of the first insulating layer 110 and has a recessed shape. This is because a portion of the connecting via 300 may be removed together in the process of removing the stopper layer temporarily disposed in the cavity C in the operation of manufacturing the cavity C and the connecting via 300. The connecting via 300 may have a structure recessed in the first surface 111 of the first insulating layer 110.

A printed circuit board according to an example may include a bridge 500.

The bridge 500 is disposed in the cavity C and may be disposed on the first surface 111 of the first insulating layer 110, and may be buried by another insulating layer. In FIG. 3, the bridge 500 is depicted as being buried by the fourth insulating layer 140, but is not limited thereto, and the present disclosure is not limited to the number of insulating layers as described above. The bridge 500 may include one or more bridge insulating layers 510 and bridge circuits 520 respectively disposed on the bridge insulating layer 510, and the bridge 500 may include a bridge pad 530 to be electrically connected. The bridge circuit 520 may include vias passing through the bridge insulating layer 510 and connecting circuit patterns in addition to the circuit patterns disposed on the bridge insulating layer 510. In FIG. 3, the bridge insulating layer 510 is described as being composed of a total of four layers, but is not limited thereto. The number of layers of the bridge insulating layer 510 and the bridge circuit 520 may be more or less than illustrated in the drawings. In addition, although the bridge circuit 520 and the bridge pad 530 are illustrated as being symmetrical with respect to the center of the bridge 500, this is just an example, and the bridge circuit 520 and the bridge pad 530 may have various shapes.

The thickness of each bridge insulating layer 510 may be smaller than the thickness of the first insulating layer 110 or other insulating layers. Also, the density of the bridge circuit 520 may be smaller than the density of the first circuit pattern 210 or other circuit patterns. For example, the bridge 500 may be smaller than other insulating layers of the printed circuit board, and the bridge 500 may form a circuit pattern relatively finer than other circuit patterns of the printed circuit board. The bridge 500 may perform a function of electrically connecting electronic components to each other through a bridge circuit 520 composed of fine circuit patterns, and may perform a function of transmitting electrical signals from the top and bottom of the printed circuit board.

The bridge insulating layer 510 may include insulating material, and in this case, the insulating material may be, for example, Photo Imagable Dielectric (PID), but the present disclosure is not limited thereto. For example, thermosetting resins such as epoxy resins, thermoplastics such as polyimide, or resins in which these resins are mixed with inorganic fillers or impregnated into glass fibers (Glass Fiber, Glass Cloth, Glass Fabric) together with inorganic fillers, for example, prepreg, Ajinomoto Build-up Film (ABF), FR-4, Bismaleimide Triazine (BT), or the like may also be used. When PID is used as the material of the bridge insulating layer 510, since the thickness of the bridge insulating layer 510 may be minimized and a photo via hole may be formed, it may be easy to design the bridge circuit 520 with high density. The insulating material of the bridge insulating layer 510 is not limited to the above-described PID material, and even if other materials are used, it is desirable to design the bridge insulating layer 510 and the bridge circuit 520 with high density.

The bridge circuit 520 is electrically connected to the printed circuit board through a circuit formed on an outermost layer and a bridge pad 530. The bridge circuit 520 may perform various functions according to the design of the corresponding layer, but includes at least a signal pattern and a signal pad. The bridge circuit 520 may perform a function of connecting different electronic components, but the present disclosure is not limited thereto. The bridge circuit 520 may use conductive materials such as copper (Cu), aluminum (Al), silver (Ag), tin (Sn), gold (Au), nickel (Ni), lead (Pb), titanium (Ti), or alloys thereof, and in detail, a metal material may be used. In FIG. 3, it is illustrated that the upper outermost layer of the bridge circuit 520 is buried by the bridge insulating layer 510, but the present disclosure is not limited thereto. The upper outermost layer of the bridge circuit 520 may have a structure protruding further than the bridge insulating layer 510.

The bridge 500 may include bridge pads 530. The bridge pad 530 may function as a means for electrically connecting the bridge 500 and the connection via 300. The bridge pad 530 may include a metal material, and may include the same type of metal material as the bridge circuit 520, but the present disclosure is not limited thereto. In FIG. 3, the bridge pad 530 is illustrated as protruding from the bridge insulating layer 510, but is not limited thereto, and may have a structure buried in the bridge insulating layer 510.

An area of one surface of the bridge pad 530 may be smaller than an area of one surface of the connection via 300. For example, in a relationship in which the bridge pad 530 is mounted on the connection via 300, the area of one surface of the bridge pad 530 is greater than the area of one surface of the connection via 300 opposite to one surface of the bridge pad 530. However, the area is not limited thereto, and the area of one surface of the bridge pad 530 and the area of one surface of the connection via 300 may be substantially the same. This is similar to that the bridge circuit 520 may have a finer circuit than the first circuit pattern 210. However, the area of one surface of the bridge pad 530 being substantially the same as the area of one surface of the connection via 300, means that the size of the bridge pad 530 may be larger than that of the bridge circuit 520 since the bridge pad 530 corresponds to a means for connecting the bridge 500 of the printed circuit board and the first circuit pattern 210.

The bridge pad 530 may be disposed to correspond to the connection via 300. The fact that the bridge pads 530 are arranged to correspond to the connecting vias 300 means that one surface of the bridge pads 530 may overlap one surface of the connecting vias 300 when considering the top view of the printed circuit board, and may have the same meaning. The bridge pad 530 may also be disposed to correspond to the recessed portion of the connection via 300. For example, one side of the bridge pad 530 may be formed smaller than the area of the recess portion of the via, and considering the top view of the printed circuit board, one side of the bridge pad 530 may be arranged so that it overlaps with the recess portion of the connection via 300.

The bonding layer 400 may be interposed between the bridge 500 and the first insulating layer 110. For example, the bonding layer 400 may be disposed between the first surface 111 of the first insulating layer 110 and the bridge 500. The bonding layer 400 may serve as a means to connect the bridge 500 to the first insulating layer 110. The bonding layer 400 may be formed thinner than the insulating layer and may be formed thin enough to be unaffected by the depth of the cavity C and the thickness of the bonding layer 400 when the bridge 500 is mounted, but the present disclosure is not limited thereto. No, it may be placed thickly. The bonding layer 400 may be disposed to bury the bridge pad 530 and the connection via 300.

The bonding layer 400 may include an anisotropic conductive film (ACF) material. For example, the bonding layer 400 may be a conductive bonding layer, and the bonding layer 400 may include conductive particles 401. The bonding layer 400 has a directionality for electrical conductivity. The fact that the bonding layer 400 has electrical conductivity directionality means that electrical conductivity along any one of the X-Y-Z axes of the anisotropic conductive layer 100 is greater than electrical conductivity along the other axes. In more detail, it may be electrically conductive for one axis and electrically insulating for the other axis, and it is not necessarily limited to this.

The bonding layer 400 may be in the form of a film in which a plurality of conductive particles 401 are dispersed in an insulating resin. The insulating resin may include a thermally polymerizable compound such as an epoxy compound or a photopolymerizable compound such as an acrylate compound, but is not limited thereto. The conductive particles 401 may include metal particles such as nickel (Ni), cobalt (Co), silver (Ag), copper (Cu), gold (Au), and palladium (Pd), alloy particles such as solder, and/or metal coated resin particles and the like, and although two or more types may be used in combination, but the present disclosure is not limited thereto. The surface of the conductive particles 401 may be subjected to an insulation treatment that does not interfere with conduction characteristics. Examples of the insulation treatment include, but are not limited to, adhesion of insulating fine particles or coating of an insulating resin. In more detail, the bonding layer 400 may include a known anisotropic conductive film (ACF), but the present disclosure is not limited thereto. The conductive particles 401 may be electrically connected to the bridge pad 530 and the connection via 300. The thickness of the bonding layer 400 may be adjusted by adjusting the diameter of the conductive particles 401. The bonding layer 400 may be disposed between the bridge 500 and the first insulating layer 110 and bonded thereto under high temperature and high pressure conditions. In this process, molding and curing of the insulating resin in the bonding layer 400 may proceed.

As the bonding layer 400 is disposed between the first insulating layer 110 and the bridge 500, the conductive particles 401 present in the bonding layer 400 may be aligned between the connection via 300 and the bridge pad 530. Looking at an enlarged view of the connection between the first insulating layer 110 and the bridge pad 530, the conductive particles 401 in the bonding layer 400 may be irregularly arranged, but conductive particles 401 are arranged in alignment between the connection via 300 and the bridge pad 530, and the connection via 300 and the bridge pad 530 may be electrically connected through the conductive particle 401.

Since the bonding layer 400 may correspond to an anisotropic conductive film, the connection via 300 and the bridge pad 530 may be electrically connected even though they do not physically contact each other. At this time, the connection via 300 and the bridge pad 530 are electrically connected, and may be electrically connected in other manner, of course. This means that the connection via 300 and the bridge pad 530 may be electrically connected through a direct shortest path. For example, even though the connection via 300 and the bridge pad 530 do not physically contact each other through the conductive particles 401 of the bonding layer 400 disposed between the connection via 300 and the bridge pad 530, it may be directly electrically connected.

The printed circuit board according to an example may further include a second circuit pattern 220 disposed on the third surface 113 of the first insulating layer 110. The second circuit pattern 220 may include a metal material, and may include the same metal material as the first circuit pattern 210, but the present disclosure is not limited thereto. The second circuit pattern 220 may perform various functions according to the design. The second circuit pattern 220 may be formed at the same time as the connection via 300 is formed, but the present disclosure is not limited thereto and may be formed in stages. The printed circuit board according to an example may further include a third circuit pattern 230, a fourth circuit pattern 240 and a fifth circuit pattern 250. Each of the third circuit pattern 230, the fourth circuit pattern 240, and the fifth circuit pattern 250 may include a metal material, and may include a metal material like the first circuit pattern 210, but the present disclosure is not limited thereto. Each of the third circuit pattern 230, the fourth circuit pattern 240, and the fifth circuit pattern 250 may perform the same function as the first circuit pattern 210 and/or the second circuit pattern 220. The fifth circuit pattern 250 may be disposed on the outermost layer of the printed circuit board and function as a pad for mounting electronic components, etc., but the present disclosure is not limited thereto, and may be connected to other components and used as an electrical signal path. The order of the circuit patterns is illustrative, and this is only indicated to correspond to the number of insulating layers, and may include a larger number of circuit patterns or a smaller number of circuit patterns. The circuit pattern does not have to be placed on the outermost layer of the printed circuit board. Since the structure in which the third circuit pattern 230 and the fourth circuit pattern 240 are disposed on each insulating layer may be the same as that of the first insulating layer 110 and the first circuit pattern 210, a detailed description thereof will be omitted. Meanwhile, the fifth circuit pattern 250 may have a structure protruding from the fourth insulating layer 140, but the present disclosure is not limited thereto. After mounting the bridge 500 in the cavity C and burying the bridge 500 with the fourth insulating layer 140, when the fifth circuit pattern 250 is disposed on one surface of the fourth insulating layer 140, the fifth circuit pattern 250 may have a structure protruding from one surface of the fourth insulating layer 140. For example, the circuit pattern disposed on the insulating layer filling the cavity C to bury the bridge 500 may only protrude from one surface of the insulating layer, but the present disclosure is not limited to the structure of the fourth insulating layer 140 and the fifth circuit pattern 250.

The printed circuit board according to an example includes first vias 201 penetrating through the first insulating layer 110 to connect the first circuit pattern 210 and the second circuit pattern 220. The first via 201 may include a metal material, and may include the same metal as the second circuit pattern 220, but the present disclosure is not limited thereto. The first via 201 may be formed simultaneously with the second circuit pattern 220, but the present disclosure is not limited thereto and may be formed in stages. In addition, the first via 201 may be formed simultaneously with the connection via 300, but the present disclosure is not limited thereto. The process of forming the first via 201 may be the same as the process of forming the connection via 300, but is not limited thereto, and a known method for forming a via may be used without limitation. The connection via 300 may have a height lower than that of the first via 201. Since both the connection via 300 and the first via 201 correspond to a configuration penetrating through the first insulating layer 110, but the connection via 300 may include a recess, the height of the connection via 300 may be lower than the height of the first via 201.

Meanwhile, the printed circuit board according to an example may include a second via 202 penetrating through the second insulating layer 120 to connect the first circuit pattern 210 and the third circuit pattern 230, a third via 203 penetrating through the third insulating layer 130 to connect the third circuit pattern 230 and the fourth circuit pattern 240, and a fourth via 204 passing through the fourth insulating layer 140 to connect the fourth circuit pattern 240 and the fifth circuit pattern 250. The second via 202, the third via 203, and the fourth via 204 may have the same structure and function as the first via 201, and a detailed description thereof will be omitted.

Meanwhile, the printed circuit board according to one example may further include an insulating layer on the other surface of the first insulating layer 110. In addition, it is not limited to the configuration illustrated in FIG. 3, and in addition, it may further include general configurations of printed circuit boards such as cores, other insulating layers, other circuit patterns, through vias and cavities, solder resist, pad surface treatment layer or the like. For example, a configuration that may be used by those skilled in the art may be further included.

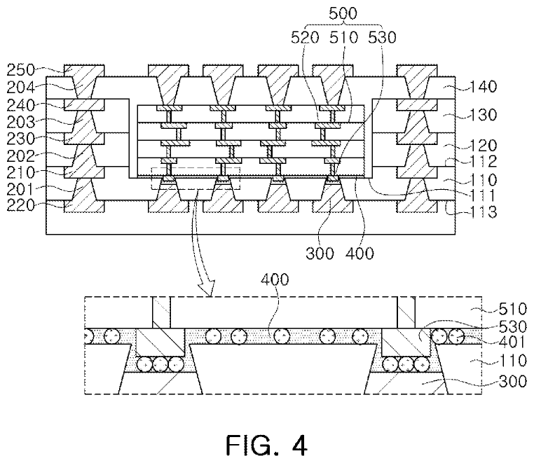

FIG. 4 is a schematic cross-sectional view of a printed circuit board according to another example.

Referring to FIG. 4, in a printed circuit board according to another example, a bridge pad 530 may be disposed in a recessed portion of a connection via 300. The area of one surface of the bridge pad 530 may be smaller than the area of the recessed portion of the connection via 300. As the bridge 500 is mounted, the bridge pad 530 may be buried up to the recess of the connection via 300. In this case, one surface of the bridge pad 530 may be disposed in the recessed portion of the connection via 300. At this time, the distance between the bridge pad 530 and the connection via 300 may become closer, so the electrical path may be shortened and reliability may be increased.

Meanwhile, in FIG. 4, one surface of the bridge 500 and one surface of the third insulating layer 130 are described as having a step, but it is not limited thereto. The size of the bridge 500 and the thickness and number of insulating layers may be properly adjusted.

Among the configurations other than the relationship between the bridge pad 530 and the connection via 300 according to the mounting of the bridge 500, the same configuration as the printed circuit board according to one example may be applied to the printed circuit board according to another example, and redundant explanations about this will be omitted.

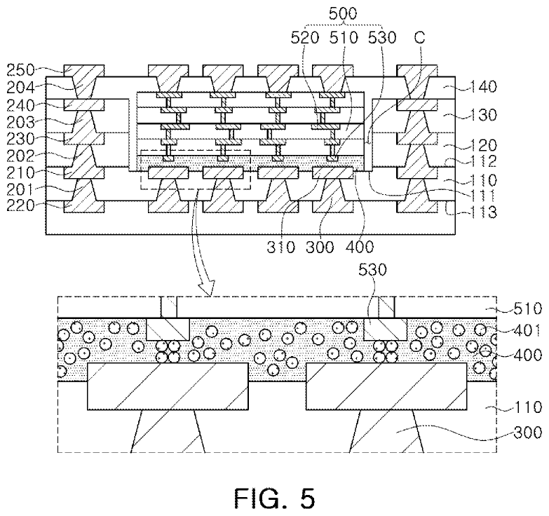

FIG. 5 is a cross-sectional view schematically illustrating a printed circuit board according to another example.

Referring to FIG. 5, the printed circuit board according to another example may further include a pad 310. The pad 310 corresponds to a means for mounting the bridge 500 in the cavity C, and may serve as a stopper in a printed circuit board according to an example. The process of manufacturing the printed circuit board according to one example includes removing the stopper, but in the printed circuit board according to another example, a pad 310 is formed, but is not removed, and may be used as a connection unit to the bridge 500.

The pad 310 may include a metal material, and may include the same metal material as the first circuit pattern 210. The pad 310 may be formed in the same process as the first circuit pattern 210, and may be formed simultaneously with the first circuit pattern 210, but is not limited thereto, and may be formed in stages with the first circuit pattern 210. Since the pad 310 may be formed simultaneously with the first circuit pattern 210, one surface of the pad 310 and one surface of the first circuit pattern 210 may be substantially coplanar. The fact that two surfaces are coplanar is a concept that includes the concept that certain two surfaces form the same surface without a step, for example, form a coplanar surface. In this case, when the two surfaces do not meet, the concept that the extended surfaces of the two surfaces form a coplanar surface may be included. Being substantially coplanar is a concept that includes approximate, and may include, for example, errors in the manufacturing process.

The pad 310 is buried on one surface of the first insulating layer 110, and one surface and a portion of the side surface of the pad 310 may protrude onto the first surface 111 of the first insulating layer 110. However, the present disclosure is not limited thereto, and although not illustrated in FIG. 5, the pad 310 may have a structure in which only one surface is exposed to one surface of the first insulating layer 110 by being buried on one surface of the first insulating layer 110.

In the operation of passing through the second insulating layer 120 and the third insulating layer 130 to form the cavity C, the seed layer disposed on the first surface 111 of the first insulating layer 110 may serve as a stopper layer. In addition, it is not limited thereto, and as described above, the pad 310 may serve as a stopper layer. Alternatively, after forming a cavity penetrating through the second insulating layer 120 and the third insulating layer 130, by further removing a portion of the first surface 111 of the first insulating layer 110, a portion of the pad 310 buried in the first insulating layer 110 may be exposed. At this time, since the degree of removal of the first insulating layer 110 may be insignificant, in the structure in which a portion of the side surface of the first circuit pattern 210 protrudes, the thickness of the protruding portion may be smaller than the thickness of the other non-protruding portion. In this manner, the pad 310 may have a structure protruding onto the first surface of the first insulating layer 110, but the present disclosure is not limited thereto, and is as described above that the side surface of the pad 310 may be buried in the first insulating layer 110.

An area of one surface of the bridge pad 530 may be smaller than an area of one surface of the pad 310, and one surface of the bridge pad 530 may be disposed to correspond to one surface of the pad 310. This is similar to the relationship between the bridge pad 530 and the connection via 300 in the printed circuit board according to an example. On the other hand, since the pad 310 protrudes into the cavity C, the distance between the bridge pad 530 and the pad 310 may be close, and the signal transfer effect may be excellent.

Among the configurations other than the pad 310, the same configuration as the printed circuit board according to one example and the printed circuit board according to another example may also be applied to the printed circuit board according to another example, and therefore, duplicate descriptions thereof will be omitted.

In the present disclosure, the meaning of cross-section may mean a cross-sectional shape when an object is vertically cut, or a cross-sectional shape when the object is viewed from a side-view. In addition, the meaning on a plane may be a shape when the object is horizontally cut, or a plane shape when the object is viewed from a top-view or bottom-view.

In the present disclosure, upper side, upper side, upper surface, etc. are used to mean directions toward a surface on which electronic components may be mounted based on the cross section of the drawing for convenience, and lower side, lower side, lower side, etc. were used in the opposite direction. However, this is a direction defined for convenience of explanation, and of course, the scope of the claims is not particularly limited by the description in this direction.

In the present disclosure, the meaning of being connected is a concept including not only being directly connected but also being indirectly connected through an adhesive layer or the like. In addition, the meaning of being electrically connected is a concept that includes both physically connected and non-connected cases. In addition, expressions such as first and second are used to distinguish one component from another, and the order and/or importance of the corresponding components is not limited. In some cases, without departing from the scope of rights, the first component may be named a second component, similarly, the second element may be referred to as the first element.

The expression “one example” used in the present disclosure does not mean the same embodiments, and is provided to emphasize and describe different unique characteristics. However, the examples presented above are not excluded from being implemented in combination with features of other examples. For example, even if a matter described in a particular example is not described in another example, it may be understood as a description related to another example, unless there is a description contradicting or contradicting the matter in another example.

As forth above, a printed circuit board in which up and down connection of signal paths may be diversified may be provided.

A printed circuit board in which a signal path may be more simply implemented.

A printed circuit board having improved reliability may be provided.

While example embodiments have been illustrated and described above, it will be apparent to those skilled in the art that modifications and variations could be made without departing from the scope of the present disclosure as defined by the appended claims.

What is claimed is:

1. A printed circuit board comprising:
a first insulating layer;
a connection via penetrating through at least a portion of the first insulating layer and having an upper surface exposed to an upper surface of the first insulating layer;
a cavity penetrating through at least a portion of the first insulating layer and having the upper surface of the first insulating layer as a bottom surface of the cavity;
a bridge disposed in the cavity and having a first bridge pad disposed on a lower side of the bridge; and
a bonding layer including conductive particles connected to the connection via and the first bridge pad.

2. The printed circuit board of claim 1, wherein the bonding layer includes an anisotropic conductive film (ACF).

3. The printed circuit board of claim 1, wherein the connection via has a recessed portion in the bottom surface of the cavity.

4. The printed circuit board of claim 1, wherein an area of a lower surface of the first bridge pad is smaller than an area of the upper surface of the connection via.

5. The printed circuit board of claim 4, wherein the lower surface of the first bridge pad is disposed to correspond to a recessed portion of the connection via.

6. The printed circuit board of claim 5, wherein the first bridge pad is disposed in the recessed portion of the connection via.

7. The printed circuit board of claim 1, wherein the upper surface of the first insulating layer has a step.

8. The printed circuit board of claim 1, further comprising:
a first circuit pattern buried in an upper side of the first insulating layer and having one surface exposed to the upper surface of the first insulating layer;
a second circuit pattern disposed on a lower surface of the first insulating layer; and
a first via passing through the first insulating layer to connect the first circuit pattern and the second circuit pattern,
wherein a height of the connection via is lower than a height of the first via.

9. The printed circuit board of claim 8, wherein the upper surface of the first insulating layer has a step, and
a size of the step on the upper surface of the first insulating layer is substantially the same as a thickness of the first circuit pattern.

10. The printed circuit board of claim 8, wherein the bridge further includes a bridge insulating layer and a bridge circuit,
wherein a circuit density of the bridge circuit is greater than a circuit density of the first circuit pattern.

11. A printed circuit board comprising:
a first insulating layer;
a pad buried in an upper side of the first insulating layer and having a portion of a side surface and an upper surface protruding toward an upper surface of the first insulating layer;
a cavity penetrating through a portion of the first insulating layer and having the upper surface of the first insulating layer as a bottom surface of the cavity;
a bridge disposed in the cavity and having a first bridge pad disposed on a lower side of the bridge; and
a bonding layer including conductive particles connected to the pad and the first bridge pad.

12. The printed circuit board of claim 11, wherein the bonding layer includes an anisotropic conductive film (ACF).

13. The printed circuit board of claim 11, wherein an area of a lower surface of the first bridge pad is smaller than an area of the upper surface of the pad.

14. The printed circuit board of claim 13, wherein the lower surface of the first bridge pad is disposed to correspond to the upper surface of the pad.

15. The printed circuit board of claim 14, wherein a thickness of a protruding portion of the side surface of the pad is smaller than a thickness of another non-protruding portion of the side surface of the pad.

16. The printed circuit board of claim 11, further comprising a first circuit pattern buried in the upper side of the first insulating layer and having one surface exposed to the upper surface of the first insulating layer,
wherein an upper surface of the first circuit pattern and the upper surface of the pad are substantially coplanar.

17. The printed circuit board of claim 11, wherein the bridge further includes a bridge insulating layer and a bridge circuit,
wherein a circuit density of the bridge circuit is greater than a circuit density of the first circuit pattern.

18. A printed circuit board comprising:
a first insulating layer in which a first via is disposed;
a second insulating layer which is disposed on the first insulating layer and in which a second via is disposed;
a cavity penetrating through the second insulating layer and a portion of the first insulating layer;
a bridge disposed in the cavity and having a bridge pad; and
a bonding layer disposed between the first insulating layer and the bridge and including conductive particles disposed between the first via and the bridge pad,
wherein the first via and the second via are tapered in a same direction.

19. The printed circuit board of claim 18, wherein one of the conductive particles is in contact with the first via, and another of the conducive particles is in contact with the bridge pad.

20. The printed circuit board of claim 18, further comprising a pad partially buried in the first insulating layer and disposed between the first via and the bridge pad,
wherein one of the conductive particles is in contact with the pad partially buried in the first insulating layer, and another of the conducive particles is in contact with the bridge pad.
